(19) United States
(12) Patent Application Publication
(10) Pub. No.: US 2024/0347321 A1
(43) Pub. Date: Oct. 17, 2024

(54) PROCESSING APPARATUS

(71) Applicant: Tokyo Electron Limited, Tokyo (JP)

(72) Inventors: Tamihiro KOBAYASHI, Tokyo (JP); Toshifumi KITAHARA, Tokyo (JP)

(21) Appl. No.: 18/633,928

(22) Filed: Apr. 12, 2024

(30) Foreign Application Priority Data
Apr. 14, 2023 (JP) 2023-066351

(51) Int. Cl. H01J 37/32

(52) U.S. Cl. CPC H01J 37/3244; H01J 37/32513; H01J 2237/166

(57) ABSTRACT

A processing apparatus includes a processing container, a main body constituting a lower portion of the processing container, and a lid constituting an upper portion of the processing container, wherein the lid includes a shower plate, a plate portion provided above the shower plate, and a connecting member for connecting the shower plate to the plate portion, a guide groove arranged to face the shower plate is provided in a lower surface of the plate portion, a protruding portion of the connecting member is accommodated in the guide groove, a position of the shower plate with respect to the plate portion is determined by accommodating the protruding portion in a first end of the guide groove, and in a state in which the protruding portion is accommodated in the first end and the lid is separated from the main body, the shower plate is suspended from the plate portion.

### CROSS-REFERENCE TO RELATED APPLICATION

This application is based upon and claims the benefit of priority from Japanese Patent Application No. 2023-066351, filed on Apr. 14, 2023, the entire contents of which are incorporated herein by reference.

### TECHNICAL FIELD

Exemplary embodiments of the present disclosure relate to a processing apparatus.

### BACKGROUND

Patent Document 1 discloses a plasma processing apparatus including a plasma processing chamber provides with a shower head and a sidewall. Maintenance of the plasma processing apparatus may be performed by separating the shower head from the plasma processing chamber and exposing the interior of the plasma processing chamber.

### PRIOR ART DOCUMENTS

### Patent Documents

Patent Document 1: Japanese Patent Laid-Open Publication No. 2022-111772

### SUMMARY

According to an embodiment of the present disclosure, a processing apparatus includes: a processing container configured to provide a processing space; a main body constituting a lower portion of the processing container; and a lid constituting an upper portion of the processing container and configured to be placed on the main body, wherein the lid includes a shower plate, a plate portion provided above the shower plate, and a connecting member fixed to the shower plate to protrude toward the plate portion and configured to connect the shower plate to the plate portion, a guide groove arranged to face the shower plate is provided in a lower surface of the plate portion, a protruding portion of the connecting member protruding toward the plate portion is accommodated in the guide groove, a position of the shower plate with respect to the plate portion is determined by accommodating the protruding portion of the connecting member fixed to the shower plate in a first end of the guide groove provided in the plate portion, and in a state in which the protruding portion is accommodated in the first end of the guide groove and the lid is separated from the main body, the shower plate is suspended from the plate portion by supporting a tip of the connecting member by a supporter provided at an opening of the guide groove.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a configuration of a plasma processing apparatus according to an exemplary embodiment.

FIG. 2 is a diagram illustrating a configuration of a lower surface of an upper electrode of the plasma processing apparatus according to the exemplary embodiment.

FIG. 3 is a diagram illustrating a state in which a connecting member which connects the upper electrode and a shower plate is guided by a guide groove provided in the lower surface of the upper electrode in the plasma processing apparatus according to the exemplary embodiment.

FIG. 4 is a diagram illustrating a state in which a lid including a shower plate is attached to a main body and an upper electrode is in close contact with the shower plate, before maintenance work on the plasma processing apparatus according to the exemplary embodiment.

FIG. 5 is a diagram illustrating a state in which a configuration including the shower plate, a support frame body, and a discharger is integrally suspended from the upper electrode by the connecting member fixed to the shower plate during the maintenance work on the plasma processing apparatus according to the exemplary embodiment.

FIG. 6 is a diagram illustrating a state in which the connecting member fixed to the shower plate is guided to an increased-width portion of the guide groove of the upper electrode so as to separate the shower plate from the upper electrode in the plasma processing apparatus according to the exemplary embodiment.

### DETAILED DESCRIPTION

Various exemplary embodiments will now be made in detail with reference to the accompanying drawings. Throughout the drawings, the same or similar parts will be denoted by the same reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In each of the drawings, the same or corresponding parts are denoted by the same or corresponding reference symbols.

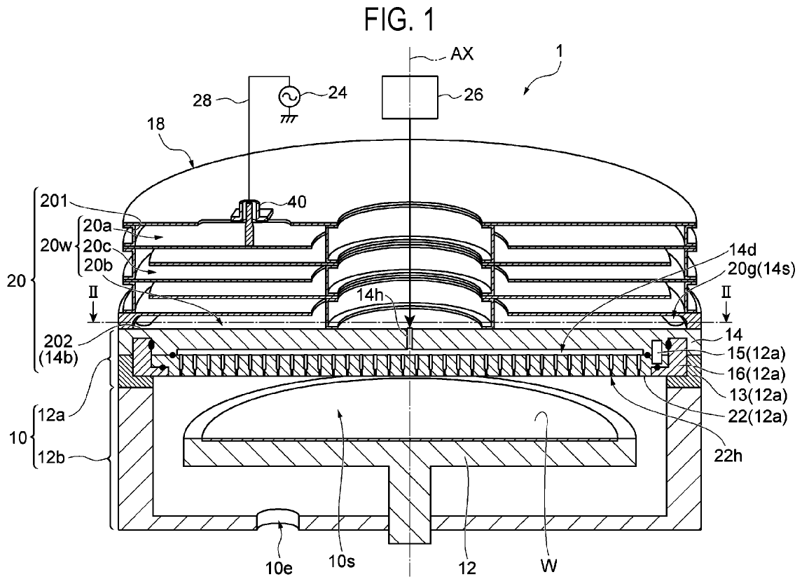

FIG. 1 is a diagram illustrating a configuration of a plasma processing apparatus 1 as an example of a processing apparatus. The plasma processing apparatus 1 illustrated in FIG. 1 includes a processing chamber 10, a substrate supporter 12, an upper electrode 14, a discharger 16, and a waveguide portion 18.

The processing container 10 has a processing space 10s provided therein to perform plasma processing. The processing space 10s has a plasma generation space. In the plasma processing apparatus 1, a substrate W is processed in the processing space 10s. The processing container 10 is made of a metal such as aluminum and is grounded.

The processing container 10 includes a main body 12b that constitutes a lower portion of the processing container 10. An upper end of the main body 12b is open. The processing container 10 includes a lid 12a that constitutes an upper portion of the processing container 10 and is configured to be placed on the main body 12b.

The lid 12a and the main body 12b may have a substantially cylindrical shape. The processing space 10s is provided inside the main body 12b. A central axial line of each of the lid 12a, the main body 12b, and the processing space 10s is an axial line AX.

The processing container 10 may have a corrosion-resistant film on a surface thereof. The corrosion-resistant film may be an yttrium oxide film, an yttrium oxide fluoride film, an yttrium fluoride film, or a ceramic film containing yttrium oxide or yttrium fluoride.

The lid 12a includes a shower plate 22, a plate portion, and a connecting member 15. The plate portion is provided above the shower plate 22. The connecting member 15 is fixed to the shower plate 22 to protrude toward the plate portion and is configured to connect the shower plate 22 to the plate portion. The plate portion may be, for example, the upper electrode 14.

The lid 12a further includes a support frame 13 and the discharger 16. The support frame 13 is configured to support the discharger 16. In a state in which the lid 12a is connected to the main body 12b, the lid 12a is placed on the main body 12b via the support frame 13, and the support frame 13 and the main body 12b are in close contact with each other. The discharger 16 is arranged between the shower plate 22 and the support frame 13 and is fixed to the shower plate 22 and the support frame 13.

The bottom of the main body 12b provides an exhaust port 10e. An exhaust device is connected to the exhaust port 10e. The exhaust device may include a vacuum pump, such as a dry pump and/or a turbomolecular pump, and an automatic pressure control valve.

The substrate supporter 12 is provided in the processing space 10s. The substrate supporter 12 is configured to substantially horizontally support the substrate W placed on an upper surface thereof. The substrate supporter 12 has a substantially disc shape. A central axial line of the substrate supporter 12 is the axial line AX.

The upper electrode 14 is provided above the substrate supporter 12 via the processing space 10s. The upper electrode 14 is made of a conductor such as a metal (e.g., aluminum) and has a substantially disc shape. A central axial line of the upper electrode 14 is the axial line AX.

The upper electrode 14 provides a plurality of slots 14s and includes a plurality of beams 14b. The plurality of slots 14s are arranged above the discharger 16. The plurality of slots 14s passes through the upper electrode 14 in a thickness direction of the upper electrode 14 (vertical direction) and extends in a circumferential direction.

The plurality of slots 14s is spaced apart from each other and arranged in the circumferential direction around the axial line AX. The plurality of slots 14s may be arranged at equal intervals. The plurality of beams 14b is arranged alternately with the plurality of slots 14s in the circumferential direction around the axial line AX. The plurality of beams 14b connects inner and outer portions of the upper electrode 14 to each other.

The discharger 16 is provided to emit electromagnetic waves to the processing space 10s therethrough. In the plasma processing apparatus 1, gas in the processing space 10s is excited by the electromagnetic waves emitted from the discharger 16 to the processing space 10sm, thus generating plasma. The electromagnetic waves emitted from the discharger 16 to the processing space 10s may be radio frequency waves such as VHF waves or UHF waves.

The discharger 16 is formed of a dielectric material such as quartz, aluminum nitride, or aluminum oxide. The discharger 16 is provided at a lateral end portion of the processing space 10s and extends in a circumferential direction around the axial line AX. The discharger 16 may have an annular shape.

The waveguide portion 18 is configured to supply electromagnetic waves to the discharger 16. The electromagnetic waves are generated by a radio-frequency power source 24, which will be described later. The electromagnetic waves propagate to the discharger 16 via the waveguide portion 18 and are introduced from the discharger 16 into the processing space 10s. The waveguide portion 18 includes a resonator 20.

The resonator 20 provides a waveguide 20w. The waveguide 20w may provide a cavity surrounded by a wall made of a conductor such as a metal (hereinafter referred to as a “conductor wall”). The conductor wall of the waveguide 20w may be made of aluminum alloy, copper, nickel, stainless steel or the like and may be coated with a low-resistance material such as silver, gold, rhodium or the like.

In an embodiment, the waveguide 20w of the resonator 20 may have a layered structure including an upper portion 20a and a lower portion 20b. The lower portion 20b extends in a radial direction with respect to the axial line AX toward a plurality of second short-circuit portions 202 around the axial line AX.

The upper portion 20a extends from a first short-circuit portion 201 in a direction opposite to a radial direction above the lower portion 20b and around the axial line AX. That is, the upper portion 20a extends from the first short-circuit portion 201 in a direction approaching the axial line AX. The waveguide 20w extends alternately in a radial direction and a direction opposite thereto in a meandering manner from the first short-circuit portion 201 to the plurality of second short-circuit portions 202 around the axial line AX.

In an embodiment, the waveguide 20w may further include an intermediate portion 20c. The intermediate portion 20c is provided between the upper portion 20a and the lower portion 20b. That is, the intermediate portion 20c is provided below the upper portion 20a and above the lower portion 20b.

One end of the intermediate portion 20c is connected to an inner end of the upper portion 20a, that is, an end of the upper portion 20a on an inner side with respect to the first short-circuit portion 201. The other end of the intermediate portion 20c is connected to an inner end of the lower portion 20b, that is, an end of the lower portion 20b on an inner side with respect to the plurality of second short-circuit portions 202. The intermediate portion 20c may extend alternately in the radial direction and a direction opposite thereto in a meandering manner around the axial line AX.

In an embodiment, the plasma processing apparatus 1 may further include a connector 40 for introducing the electromagnetic waves into the waveguide 20w. The connector 40 is a portion of a coaxial line 28. The radio-frequency power source 24 is coupled to the upper portion 20a via the coaxial line 28 and the connector 40. The connector 40 may be coupled to the upper portion 20a at a position spaced apart from the axial line AX in the radial direction.

In an embodiment, the plasma processing apparatus 1 may further include the shower plate 22. The shower plate 22 may be made of a metal such as aluminum. The discharger 16 extends so as to surround the shower plate 22.

The discharger 16 and the shower plate 22 are arranged so as to close an upper opening of the processing container 10. The shower plate 22 provides a plurality of gas holes 22h. The plurality of gas holes 22h extends in a thickness direction (vertical direction) of the shower plate 22 and passes through the shower plate 22.

The shower plate 22 is provided below the upper electrode 14. The shower plate 22 and the upper electrode 14 define a gas diffusion space 14d therebetween. A central axial line of the gas diffusion space 14d may be the axial line AX. The plurality of gas holes 22h of the shower plate 22 is connected to the gas diffusion space 14d. The upper electrode 14 also provides an inlet 14h. The inlet 14h may extend on the axial line AX. The inlet 14h is connected to the gas diffusion space 14d.

A gas supplier 26 is connected to the gas diffusion space 14d. Gas output from the gas supplier 26 is supplied to the processing space 10s via the inlet 14h, the gas diffusion space 14d, and the plurality of gas holes 22h.

The plasma processing apparatus 1 may further include the radio-frequency power source 24. The radio-frequency power source 24 is electrically coupled to the waveguide of the resonator 20 and is configured to generate radio-frequency power, frequency of which is variable. Electromagnetic waves introduced into the processing container 10 are generated based on the radio-frequency power generated by the radio-frequency power source 24.

The radio-frequency power source 24 may be directly connected to the waveguide of the resonator 20 using the coaxial line 28. That is, the radio-frequency power source 24 may be coupled to the waveguide of the resonator 20 without going through a matcher for impedance matching.

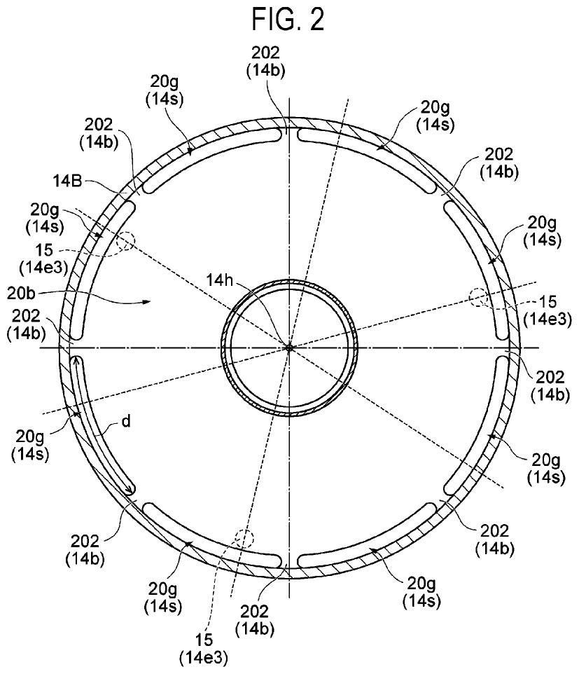

Hereinafter, FIG. 2 will be referred together with FIG. 1. FIG. 2 is a diagram illustrating a configuration of the upper electrode 14 of the plasma processing apparatus 1. FIG. 2 is a cross-sectional view taken along line II-II in FIG. 1 and is a diagram illustrating the configuration of the upper surface of the upper electrode 14.

The resonator 20 includes the first short-circuit portion 201 and the plurality of second short-circuit portions 202. The first short-circuit portion 201 constitutes one end of the waveguide 20w of the resonator 20. In an embodiment, the first short-circuit portion 201 may extend in the circumferential direction around the axial line AX.

The plurality of second short-circuit portions 202 constitutes the other end of the waveguide 20w of the resonator 20. The plurality of second short-circuit portions 202 is arranged (at equal intervals) axisymmetrically in the circumferential direction around the axial line AX. The plurality of beams 14b constitutes the plurality of second short-circuit portions 202.

The resonator 20 provides a plurality of gaps 20g. The plurality of gaps 20g is arranged alternately with respect to the plurality of second short-circuit portions 202 in the circumferential direction around the axial line AX. The plurality of gaps 20g is electromagnetically coupled to the discharger 16. The plurality of slots 14s constitute the plurality of gaps 20g.

The plasma processing apparatus 1 may include at least three connecting members 15 provided in a circumferential direction of the upper electrode 14. The plasma processing apparatus 1 may include a plurality of guide grooves 14e equal in number to the at least three connection members 15, which are respectively provided at positions facing the at least three connection members 15. The at least three connecting members 15 and the plurality of guide grooves 14e equal in number to the at least three connecting members 15 are arranged at unequal intervals in the circumferential direction of the upper electrode 14.

In the plasma processing apparatus 1, resonance of electromagnetic waves occurs

between the plurality of second short-circuit portions 202, that is, the plurality of beams 14b, and the first short-circuit portion 201. The electromagnetic waves resonating in the resonator 20 are supplied to the discharger 16 via the plurality of gaps 20g, that is, the plurality of slots 14s. The electromagnetic waves supplied to the discharger 16 are discharged from the discharger 16 to the processing space 10s.

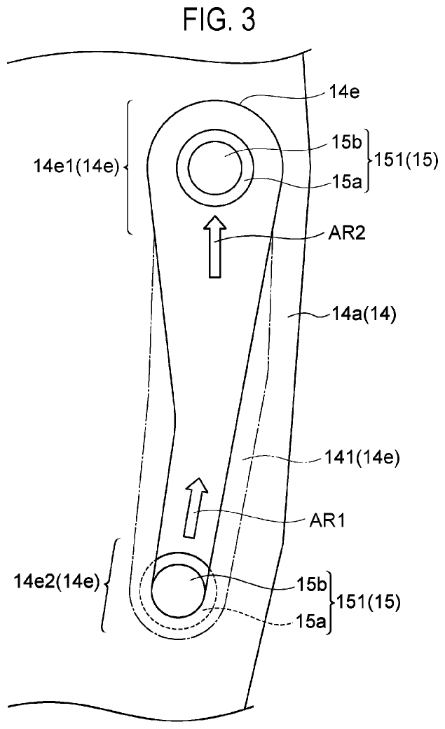

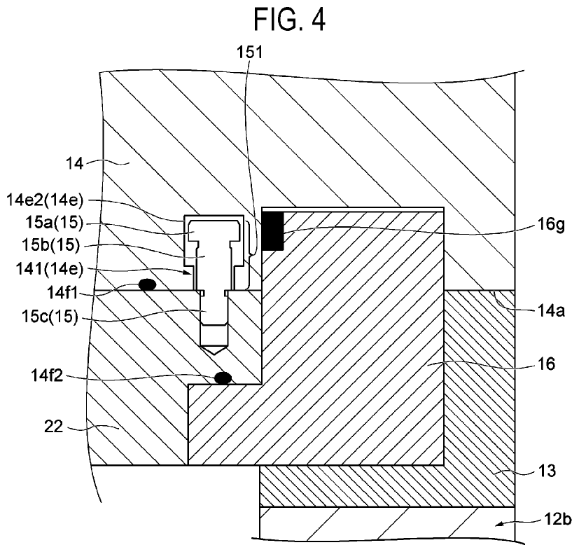

Hereinafter, FIGS. 3 and 4 will be referred together with FIGS. 1 and 2. FIG. 3 is a diagram illustrating a state in which the connecting member 15 connecting the upper electrode 14 and the shower plate 22 is guided by the guide groove 14e provided on a lower surface 14a of the upper electrode 14. FIG. 4 is a diagram illustrating a state in which the lid 12a including the shower plate 22 is attached to the main body 12b and the upper electrode 14 is in close contact with the shower plate 22, before maintenance work on the plasma processing apparatus 1.

The guide groove 14e arranged to face the shower plate 22 is provided on the lower surface 14a of the upper electrode 14, which is an example of the plate portion. A protruding portion 151 of the connecting member 15 that protrudes from the shower plate 22 toward the upper electrode 14 is accommodated in the guide groove 14e. When the protruding portion 151 is accommodated in one end (a decreased-width portion 14e2) of the guide groove 14e, a position of the shower plate 22 with respect to the upper electrode 14 is determined.

A more specific description will be given later. The connecting member 15 has a head top portion 15a provided at a tip thereof, and a shaft portion 15b connected to the head top portion 15a and having a smaller diameter than the head top portion 15a. The head top portion 15a and the shaft portion 15b provide the protruding portion 151.

The connecting member 15 has a lower end portion 15c provided at a lower end of the shaft portion 15b inside the shower plate 22. When the lower end portion 15c is fixed to the shower plate 22 inside the shower plate 22, the connecting member 15 is fixed to the shower plate 22.

The decreased-width portion 14e2 having an opening smaller in diameter than the head top portion 15a and larger in diameter than the shaft portion 15b is provided at one end of the guide groove 14e. An increased-width portion 14e1 having an opening larger in diameter than the head top portion 15a is provided at the other end of the guide groove 14e. In a state in which the protruding portion 151 is accommodated in the decreased-width portion 14e2, and thus the lid 12a is separated from the main body 12b, the head top portion 15a is supported by a supporter 141.

The connecting member 15, the protruding portion 151 of which is accommodated in the decreased-width portion 14e2, may guide (move) the protruding portion 151 to the increased-width portion 14e1 in a direction AR1 and a direction AR2. The connecting member 15, the protruding portion 151 of which is accommodated in the increased-width portion 14e1, may be drawn out from the guide groove 14e via the increased-width portion 14e1.

In a state in which the protruding portion 151 is accommodated in the decreased-width portion 14e2 and the lid 12a is placed on the main body 12b, the upper electrode 14 is in close contact with the shower plate 22 due to gravity, and the head top portion 15a and the supporter 141 are separated from each other.

The lid 12a includes a seal member 14f1 and a seal member 14f2. The seal member 14f1 is provided at a place in which the upper electrode 14 and the shower plate 22 are in contact with each other. The seal member 14f2 is provided in a place in which the shower plate 22 and the discharger 16 are in contact with each other. Both the seal member 14f1 and the seal member 14f2 may be, for example, O-rings and correspond to first O-rings that partition the processing space 10s from the outside of the processing container 10.

The lid 12a includes a seal member 16g corresponding to a second O-ring that partitions the processing space 10s from an external space of the processing container 10. The seal member 16g is provided in, for example, a place in which the discharger 16 and the upper electrode 14 are in contact in a state where the upper electrode 14 is in close contact with the shower plate 22. The seal member 16g is configured to airtightly isolate the processing space 10s from the outside of the processing container 10. In this way, a double O-ring structure constituted with the seal member 14f1 and the seal member 16g, and a double O-ring structure constituted with the seal member 14f2 and the seal member 16g are formed in the lid 12a.

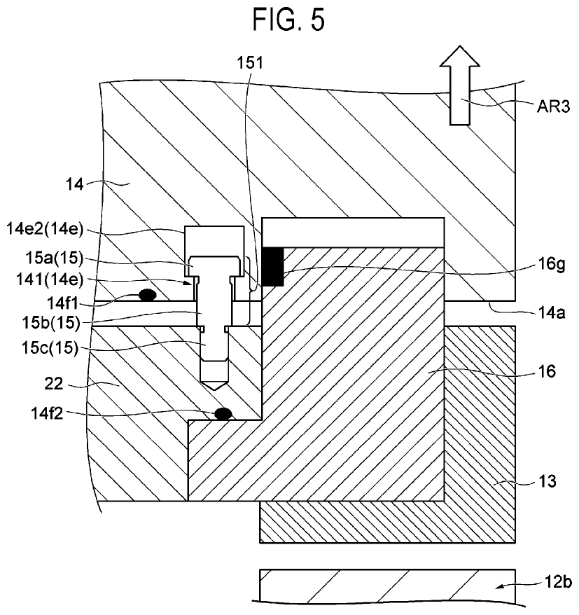

FIG. 5 will be referred to later. FIG. 5 is a diagram illustrating a state in which a configuration including the shower plate 22, the support frame 13, and the discharger 16 is integrally suspended from the upper electrode 14 by the connecting member 15 fixed to the shower plate 22, during the maintenance work on the plasma processing apparatus 1.

In the maintenance work of the plasma processing apparatus 1, the upper electrode 14 of the lid 12a is lifted in a direction AR3 (a reverse vertical direction) so that the lid 12a is separated from the main body 12b to expose the processing space 10s, which is the interior of the main body 12b, to the outside. In this case, the protruding portion 151 is accommodated in one end (the decreased-width portion 14e2) of the guide groove 14e, and thus the lid 12a is separated from the main body 12b. In this state, the upper electrode 14 is separated from the shower plate 22. The tip (the head top portion 15a) of the connecting member 15 is supported by the supporter 141 provided at an opening of the guide groove 14e in the decreased-width portion 14e2, so that the shower plate 22 is suspended from the upper electrode 14 via the connecting member 15. In this case, the configuration including the shower plate 22, the support frame 13, and the discharger 16 is integrally suspended from the upper electrode 14.

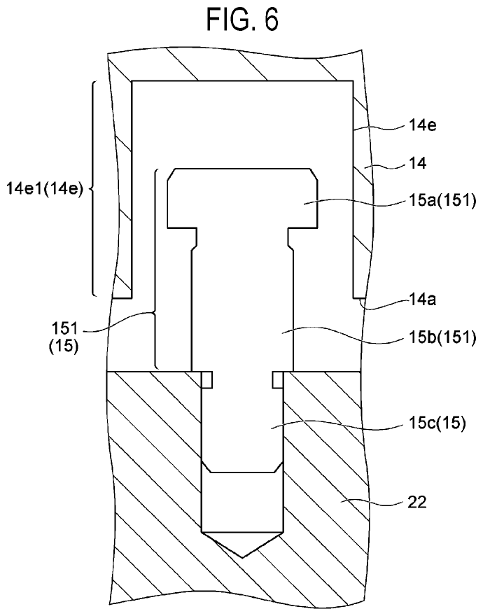

FIG. 6 will be referred to later. FIG. 6 is a diagram illustrating a state in which the connecting member 15 fixed to the shower plate 22 is guided from the decreased-width portion 14e2 to the increased-width portion 14e1 of the guide groove 14e so as to separate the shower plate 22 from the upper electrode 14.

The state shown in FIG. 6 may occur by rotating the shower plate 22 in the circumferential direction of the upper electrode 14 from the state in which the protruding portion 151 is accommodated in the decreased-width portion 14e2 to move the protruding portion 151 from the decreased-width portion 14e2 to the increased-width portion 14e1.

According to the above description, in the maintenance work of the plasma processing apparatus 1 performed in the state in which the protruding portion 151 is accommodated in the decreased-width portion 14e2 of the guide groove 14e, and thus the lid 12a is separated from the main body 12b, the shower plate 22 is suspended from the upper electrode 14. In this case, a configuration including the shower plate 22, the support frame 13, and the discharger 16 is integrally suspended from the upper electrode 14. This eliminates a need to provide an operation of operating screws to separate the shower plate 22 from the upper electrode 14. Thus, the maintenance work on the plasma processing apparatus 1 is alleviated. Further, when the protruding portion 151 of the connecting member 15 is accommodated in the decreased-width portion 14e2 of the guide groove 14e, the position of the shower plate 22 with respect to the upper electrode 14 is determined. This eliminates a need to provide an operation of positioning the shower plate 22 with respect to the upper electrode 14. Further, normally, the positioning and fixation of the shower plate 22 with respect to the upper electrode 14 may be performed by operating screws from above the upper electrode 14, as in the structure disclosed in Patent Document 1. However, when a structure such as the waveguide portion 18 is provided above the upper electrode 14, it is necessary to disassemble and remove the structure above the upper electrode 14 in order to turn the screws. However, in the structure of the exemplary embodiment described above, there is no need to disassemble and remove the structure provided above the upper electrode 14. This makes it possible to alleviate the maintenance work for the processing apparatus. In addition, when implementing the double O-ring structure in the structure as in Patent Document 1, places where required O-rings are installed may be increased. In contrast, in the structure of the above-described exemplary embodiment, the places where the O-rings are installed may be significantly reduced. This makes it possible to alleviate the maintenance work.

Although various exemplary embodiments have been described above, the present disclosure is not limited to the above-described exemplary embodiments, and various additions, omissions, substitutions, and changes may be made. In addition, it is possible to form other embodiments by combining elements from other embodiments.

Various exemplary embodiments included in the present disclosure are now described in [E1] to [E9] below.

[E1]

A processing apparatus includes

a processing container configured to provide a processing space,

a main body constituting a lower portion of the processing container, and

a lid constituting an upper portion of the processing container and configured to be placed on the main body,

wherein the lid includes a shower plate, a plate portion provided above the shower plate, and a connecting member fixed to the shower plate to protrude toward the plate portion and configured to connect the shower plate to the plate portion,

wherein a guide groove arranged to face the shower plate is provided on a lower surface of the plate portion,

wherein a protruding portion of the connecting member protruding toward the plate portion is accommodated in the guide groove,

wherein a position of the shower plate with respect to the plate portion is determined by accommodating the protruding portion of the connecting member fixed the shower plate in a first end of the guide groove provided on the plate portion, and

wherein, in a state in which the protruding portion is accommodated in the first end, and the lid is separated from the main body, the shower plate is suspended from the plate portion by supporting a tip of the connecting member by a supporter provided at an opening of the guide groove.

Therefore, in maintenance of the processing apparatus performed in the state in which the protruding portion is accommodated in the first end of the guide groove, and the lid is separated from the main body, the shower plate is suspended from the plate portion. Thus, since an operation of operating screws to separate the shower plate from the plate portion is not necessary, the maintenance work for the processing apparatus is alleviated. Further, the position of the shower plate with respect to the plate portion is determined by accommodating the protruding portion of the connecting member in the decreased-width portion of the guide groove. Therefore, an operation of positioning the shower plate with respect to the plate portion is not necessary.

[E2]

In the processing apparatus of [E1] above, the lid includes a seal member having a double O-ring structure, and

the seal member is configured to airtightly isolate the processing space from an outside of the processing container.

[E3]

In the processing apparatus of [E1] or [E2] above, the connecting member has a head top portion provided at the tip thereof, and a shaft portion connected to the head top portion and having a smaller diameter than the head top portion, and

the head top portion and the shaft portion provide the protruding portion.

[E4]

In the processing apparatus of [E3] above, a decreased-width portion having an opening smaller in diameter than the head top portion and larger in diameter than the shaft portion is provided at the first end of the guide groove, and

the head top portion is supported by the supporter in a state in which the protruding portion is accommodated in the decreased-width portion, and the lid is separated from the main body.

[E5]

In the processing apparatus of [E4] above, an increased-width portion having an opening larger in diameter than the head top portion is provided at a second end of the guide groove.

[E6]

In the processing apparatus of [E5] above, the protruding portion is configured to move to the increased-width portion by rotating the shower plate in a circumferential direction of the plate portion in the state in which the protruding portion is accommodated in the decreased-width portion.

[E7]

In the processing apparatus of any one of [E1] to [E6] above, the connecting member includes at least three connecting members provided around the circumferential direction of the plate portion, and

the guide groove includes a plurality of guide grooves equal in number to the at least three connecting members and provided at positions facing the at least three connecting members, respectively.

[E8]

In the processing apparatus of [E7] above, the at least three connecting members and the plurality of guide grooves equal in number to the at least three connecting members are arranged at unequal intervals in the circumferential direction.

[E9]

In the processing apparatus of to any one of [E1] to [E8] above, the plate portion is an upper electrode.

According to the present disclosure in some embodiments, it is possible to provide a technique for alleviating a maintenance work on a processing apparatus.

From the foregoing description, it should be understood that various embodiments of the present disclosure have been described herein for purposes of illustration, and that various modifications can be made without departing from the scope and spirit of the present disclosure. Accordingly, the various embodiments disclosed herein are not intended to be limiting, and the true scope and spirit of the present disclosure are indicated by the appended claims.

What is claimed is:

1. A processing apparatus comprising:
a processing container configured to provide a processing space;
a main body constituting a lower portion of the processing container; and
a lid constituting an upper portion of the processing container and configured to be placed on the main body,
wherein the lid includes a shower plate, a plate portion provided above the shower plate, and a connecting member fixed to the shower plate to protrude toward the plate portion and configured to connect the shower plate to the plate portion,
wherein a guide groove arranged to face the shower plate is provided in a lower surface of the plate portion,
wherein a protruding portion of the connecting member protruding toward the plate portion is accommodated in the guide groove,
wherein a position of the shower plate with respect to the plate portion is determined by accommodating the protruding portion of the connecting member fixed to the shower plate in a first end of the guide groove provided in the plate portion, and
wherein, in a state in which the protruding portion is accommodated in the first end of the guide groove and the lid is separated from the main body, the shower plate is suspended from the plate portion by supporting a tip of the connecting member by a supporter provided at an opening of the guide groove.

2. The processing apparatus of claim 1, wherein the lid includes a seal member having a double O-ring structure, and
wherein the seal member is configured to airtightly isolate the processing space from an outside of the processing container.

3. The processing apparatus of claim 1, wherein the connecting member has a head top portion provided at the tip of the connecting member and a shaft portion connected to the head top portion and having a smaller diameter than the head top portion, and
wherein the head top portion and the shaft portion provide the protruding portion.

4. The processing apparatus of claim 3, wherein a decreased-width portion having an opening smaller in diameter than the head top portion and larger in diameter than the shaft portion is provided at the first end of the guide groove, and
wherein the head top portion is supported by the supporter in a state in which the protruding portion is accommodated in the decreased-width portion so that the lid is separated from the main body.

5. The processing apparatus of claim 4, wherein an increased-width portion having an opening larger in diameter than the head top portion is provided at a second end of the guide groove.

6. The processing apparatus of claim 5, wherein the protruding portion is configured to move to the increased-width portion by rotating the shower plate in a circumferential direction of the plate portion in the state in which the protruding portion is accommodated in the decreased-width portion.

7. The processing apparatus of claim 1, wherein the connecting member includes at least three connecting members provided around a circumferential direction of the plate portion, and the guide groove includes a plurality of guide grooves equal in number to the at least three connecting members and provided at positions facing the at least three connecting members, respectively.

8. The processing apparatus of claim 7, wherein the at least three connecting members and the plurality of guide grooves equal in number to the at least three connecting members are arranged at unequal intervals in the circumferential direction.

9. The processing apparatus of claim 1, wherein the plate portion is an upper electrode.
